(19) United States
(12) Patent Application Publication
(10) Pub. No.: US 2024/0047943 A1
(43) Pub. Date: Feb. 8, 2024

(54) SEMICONDUCTOR LASER ELEMENT

(71) Applicant: NICHIA CORPORATION, Anan-shi (JP)

(72) Inventors: Hisashi OGAWA, Yokohama-shi (JP); Masaki OMORI, Toshima-ku (JP)

(73) Assignee: NICHIA CORPORATION, Anan-shi (JP)

(21) Appl. No.: 18/363,891

(22) Filed: Aug. 2, 2023

(30) Foreign Application Priority Data
Aug. 5, 2022 (JP) 2022-125761

(51) Int. Cl. H01S 5/10; H01S 5/20; H01S 5/12

(52) U.S. Cl. CPC H01S 5/1014; H01S 5/20; H01S 5/12; H01S 5/34346

(57) ABSTRACT

A semiconductor laser element includes a substrate, and a semiconductor layer portion disposed on the substrate and including a waveguide including an active layer. The waveguide includes a wide portion including a first diffraction grating, and a narrow portion that has a narrower waveguide width than the wide portion and through which light generated in the active layer propagates in a transverse multimode. The waveguide includes a first end surface including an end surface of the narrow portion, and a second end surface located on a side opposite to the first end surface. The wide portion is continuously connected to the narrow portion, and includes a first region having a waveguide width increasing from the first end surface side toward the second end surface side.

### CROSS-REFERENCE TO RELATED APPLICATIONS

The present application claims priority under 35 U.S.C. § 119 to Japanese Patent Application No. 2022-125761, filed Aug. 5, 2022, the contents of which are hereby incorporated by reference in their entirety.

### BACKGROUND

### 1. Technical Field

The present disclosure relates to a semiconductor laser element.

### 2. Description of Related Art

In recent years, with increasing uses of semiconductor laser elements, there has been an increasing demand for transverse multimode semiconductor laser elements, which are likely to provide an output higher than that of transverse single-mode semiconductor laser elements. For example, Japanese Patent Publication No. 2011-151238 (“Patent Document 1”) discloses a transverse multimode semiconductor laser element.

### SUMMARY

However, the transverse multimode semiconductor laser element disclosed in Patent Document 1 has a great variation in longitudinal mode, that is, a great variation in oscillation wavelengths.

Thus, an object of the present disclosure is to provide a transverse multimode semiconductor laser element having a small variation in oscillation wavelengths.

A semiconductor laser element according to one embodiment of the present disclosure includes a substrate, and a semiconductor layer portion disposed on the substrate and including a waveguide including an active layer, in which the waveguide includes a wide portion including a first diffraction grating, and a narrow portion that has a narrower waveguide width than the wide portion and through which light generated in the active layer propagates in a transverse multimode, the waveguide includes a first end surface including an end surface of the narrow portion, and a second end surface located on a side opposite to the first end surface, and the wide portion is continuously connected to the narrow portion, and includes a first region having a waveguide width increasing from the first end surface side toward the second end surface side.

As the semiconductor laser element according to one embodiment of the present disclosure, a transverse multimode semiconductor laser element having a small variation in oscillation wavelengths can be provided.

### BRIEF DESCRIPTION OF THE DRAWINGS

A more complete appreciation of embodiments of the disclosure and many of the attendant advantages thereof will be readily obtained by reference to the following detailed description when considered in connection with the accompanying drawings.

FIG. 1 is a schematic top view of a semiconductor laser element of a first embodiment according to the present disclosure.

FIG. 2 is a schematic cross-sectional view taken along line II-II of the semiconductor laser element illustrated in FIG. 1.

FIG. 3 is a schematic cross-sectional view taken along line III-III of the semiconductor laser element illustrated in FIG. 1.

FIG. 4 is a schematic cross-sectional view taken along line IV-IV of the semiconductor laser element illustrated in FIG. 1.

FIG. 5A is a schematic cross-sectional view illustrating a step in a method for manufacturing the semiconductor laser element according to the first embodiment.

FIG. 5B is a schematic cross-sectional view illustrating a step in the method for manufacturing the semiconductor laser element according to the first embodiment.

FIG. 5C is a schematic cross-sectional view illustrating a step in the method for manufacturing the semiconductor laser element according to the first embodiment.

FIG. 5D is a schematic cross-sectional view illustrating a step in the method for manufacturing the semiconductor laser element according to the first embodiment.

FIG. 5E is a schematic top view illustrating a step in the method for manufacturing the semiconductor laser element according to the first embodiment.

FIG. 5F is a schematic cross-sectional view illustrating a step in the method for manufacturing the semiconductor laser element according to the first embodiment.

FIG. 6 is a schematic top view of a semiconductor laser element according to a second embodiment of the present disclosure.

FIG. 7 is a schematic top view of a semiconductor laser element according to a third embodiment of the present disclosure.

FIG. 8 is a schematic top view of a light source device according to a fourth embodiment of the present disclosure.

FIG. 9A is a graph showing a relationship between a waveguide width and an effective refractive index for each transverse mode in a simulation.

FIG. 9B is a graph showing a relationship between a waveguide width and a Bragg wavelength at a position where a diffraction grating is provided in a simulation.

### DETAILED DESCRIPTION

Embodiments, modified examples, and examples for implementing the present disclosure will be described below with reference to the accompanying drawings. A semiconductor laser element according to the present disclosure described below is intended to embody technical concepts of the invention according to the present disclosure, and the invention according to the present disclosure is not limited to the following description unless otherwise specifically stated.

In each drawing, members having identical functions may be denoted by the same reference characters. In view of the ease of explanation or understanding of the main points, the embodiments, modified examples, or examples may be illustrated separately for convenience, but the partial substitutions or combinations of the configurations illustrated in different embodiments, modified examples, and examples are possible. In the embodiments, modified examples, and examples described below, descriptions of matters that are the same as those already described will be omitted, and only different points are described. In particular, similar actions and effects according to similar configurations shall not be mentioned sequentially in each embodiment, modified example, and example. The size, positional relationship, and the like of the members illustrated in the drawings may be exaggerated in order to clarify explanation. In the present specification, “orthogonal” and “parallel” each include a deviation of ±0.1 degree.

### 1. FIRST EMBODIMENT

A semiconductor laser element according to a first embodiment of the present disclosure includes a substrate, and a semiconductor layer portion disposed on the substrate and including a waveguide including an active layer. The waveguide includes a wide portion including a first diffraction grating, and a narrow portion that has a narrower waveguide width than the wide portion and in which light generated in the active layer propagates in a transverse multimode. The waveguide includes a first end surface including an end surface of the narrow portion, and a second end surface located on a side opposite to the first end surface. The wide portion is continuously connected to the narrow portion, and includes a first region having a waveguide width increasing from the first end surface side toward the second end surface side.

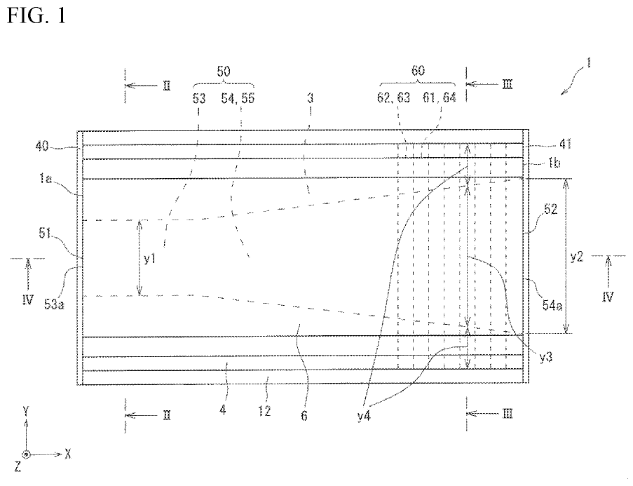

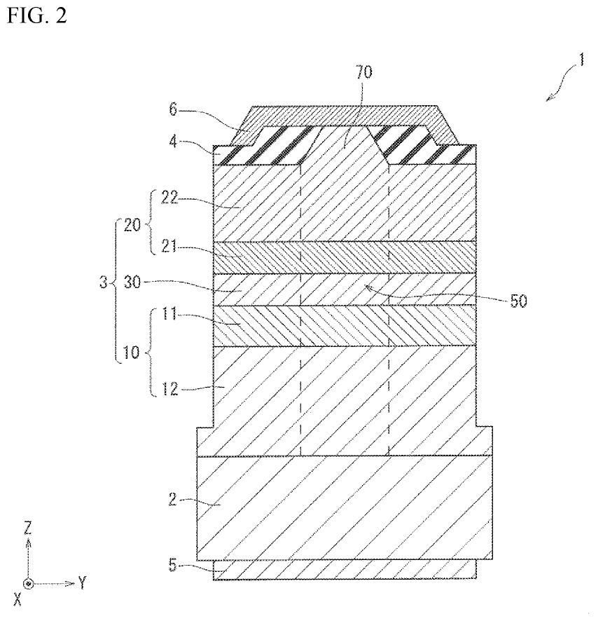

A semiconductor laser element and a method for manufacturing the semiconductor laser element according to a first embodiment will be described below with reference to FIGS. 1 to 5F. As illustrated in FIG. 2, a semiconductor laser element 1 according to the first embodiment includes a substrate 2 and a semiconductor layer portion 3. The semiconductor layer portion 3 is disposed on the substrate 2. The semiconductor layer portion 3 includes a waveguide 50 including an active layer 30. In the present specification, a first direction X means a direction in which laser light is oscillated (i.e., a direction in which laser light resonates). A second direction Y means a width direction of the waveguide 50. A third direction Z means a layering direction of the semiconductor layer portion 3 (i.e., a direction from the substrate 2 toward the semiconductor layer portion 3). Note that the first direction X, the second direction Y, and the third direction Z are orthogonal to each other. The waveguide 50 extends along the first direction X.

As illustrated in FIG. 1, the waveguide 50 includes a wide portion 54 and a narrow portion 53.

The waveguide 50 further includes a first end surface 51 and a second end surface 52 located on a side opposite to the first end surface 51. The first end surface 51 includes an end surface 53a of the narrow portion 53.

The wide portion 54 includes a diffraction grating 60 (also referred to first diffraction grating). The wide portion 54 is continuously connected to the narrow portion 53. The wide portion 54 includes a first region 55 having a waveguide width increasing from the first end surface 51 side toward the second end surface 52 side.

The narrow portion 53 has a narrower waveguide width than the wide portion 54. In the narrow portion 53, light generated in the active layer 30 propagates in a transverse multimode.

Substrate

The substrate 2 used in the semiconductor laser element 1 according to the present disclosure is, for example, a semiconductor substrate. The substrate 2 is, for example, a nitride semiconductor substrate such as a GaN substrate. The nitride semiconductor substrate may contain an n-type impurity. An element serving as the n-type impurity may be, for example, O, Si, or Ge. The nitride semiconductor substrate may be used as the substrate 2, and an upper surface thereof may be a +c plane (i.e., a (0001) plane). In the present embodiment, the c plane is not limited to a plane exactly coinciding with the (0001) plane, but includes a plane having an off-angle of ±1 degree or less, preferably ±0.03 degrees or less. The semiconductor laser element 1 need not include the substrate 2. As the upper surface of the substrate, a nonpolar plane (M plane or A plane) or a semipolar plane (R plane) may be used.

Semiconductor Layer Portion

As illustrated in FIGS. 2 to 4, the semiconductor layer portion 3 includes a first layer 10, the active layer 30, and a second layer 20 in this order from the substrate 2 side. In the semiconductor laser element 1, the first layer 10 and the second layer 20 may be group III-V semiconductor layers. Examples of the group III-V semiconductor layer include a nitride semiconductor layer formed having a composition of In_{α}Al_{β}Ga_{1-α-β}N, (0≤α, 0≤β, α+β≤1).

Examples of the element serving as the n-type impurity used for the nitride semiconductor layer include Si and Ge. Further, examples of an element serving as a p-type impurity include Mg. In this case, the nitride semiconductor layer of each conductive type can be formed.

First Layer

The first layer 10 includes one or more semiconductor layers containing the n-type impurity. The first layer 10 may include an undoped layer that is not intentionally doped with impurities. The first layer 10 includes, in order from the substrate 2 side, a second n-side semiconductor layer 12 having, as its refractive index, a second refractive index n2, and a first n-side semiconductor layer 11 having, as its refractive index, a first refractive index n1. The first layer 10 may include a layer other than these layers.

The first refractive index n1 and the second refractive index n2 are lower than a refractive index n5 of the active layer 30. The first refractive index n1 and the second refractive index n2 are different from each other. For example, the first refractive index n1 is higher than the second refractive index n2.

The second n-side semiconductor layer 12 is disposed between the active layer 30 and the substrate 2. The second n-side semiconductor layer 12 may be, for example, a nitride semiconductor layer. Examples of the nitride semiconductor include AlGaN and GaN. A film thickness of the second n-side semiconductor layer 12 may be in a range from 0.45 μm to 3.0 μm. The n-type impurity content may be in a range from 1×10¹⁷ cm⁻to 5×10¹⁸ cm⁻³. In the first embodiment, the second n-side semiconductor layer 12 can function as, for example, an n-side cladding layer.

The first n-side semiconductor layer 11 is disposed between the active layer 30 and the second n-side semiconductor layer 12. The first n-side semiconductor layer 11 may be, for example, a nitride semiconductor layer. Examples of the nitride semiconductor include AlGaN, GaN, and InGaN. A film thickness of the first n-side semiconductor layer 11 may be, for example, in a range from 0.05 μm to 0.5 μm. The n-type impurity content may be in a range from 1×10¹⁷ cm⁻³ to 5×10¹⁸ cm⁻³. In the first embodiment, the first n-side semiconductor layer 11 can function as, for example, an n-side light guide layer.

Active Layer

The active layer 30 is disposed on the first n-side semiconductor layer 11. The active layer 30 emits light having a wavelength in a range from 360 nm to 520 nm, for example. The active layer 30 may have a quantum well structure formed of one or more well layers and a plurality of barrier layers. The well layer and the barrier layer may be made of, for example, GaN, InGaN, AlGaN, or AlInGaN. The well layer may be made of, for example, AlGaN, GaN, or InGaN, which is a nitride semiconductor having a band gap smaller than that of the barrier layer. The active layer 30 may have a multiple quantum well structure or a single quantum well structure. Note that any one or both of the well layer and the barrier layer may contain an impurity.

Second Layer

The second layer 20 including one or more semiconductor layers containing p-type impurities (hereinafter also referred to as p-side semiconductor layers) is formed on the active layer 30. The second layer 20 may include an undoped layer that is not intentionally doped with an impurity. The second layer 20 may include a p-side light guide layer and a p-side cladding layer, or may include a layer other than these layers. Specifically, the second layer 20 includes, in order from the substrate 2 side (i.e., from the active layer 30 side), a first p-side semiconductor layer 21 having, as its refractive index, a third refractive index n3, and a second p-side semiconductor layer 22 having, as its refractive index, a fourth refractive index n4. The second layer 20 may include a layer other than these layers. The third refractive index n3 and the fourth refractive index n4 are lower than the refractive index n5 of the active layer 30. The third refractive index n3 and the fourth refractive index n4 are different from each other. For example, the third refractive index n3 is higher than the fourth refractive index n4.

The first p-side semiconductor layer 21 may be, for example, a nitride semiconductor layer. Examples of the nitride semiconductor include AlGaN and GaN. A film thickness of the first p-side semiconductor layer 21 may be in a range from 0.05 μm to 0.25 μm. The first p-side semiconductor layer 21 may be an undoped layer, and may contain a p-type impurity at a concentration in a range from 1×10¹⁶ cm⁻³ to 1×10¹⁸ cm⁻³. In the first embodiment, the first p-side semiconductor layer 21 can function as, for example, a p-side light guide layer.

The second p-side semiconductor layer 22 may be, for example, a nitride semiconductor layer. Examples of the nitride semiconductor include AlGaN and GaN. The second p-side semiconductor layer 22 may have a single-layer structure or a multilayer structure in which nitride semiconductor layers having different compositions are layered. The p-type impurity content may be in a range from 1×10¹⁷ cm⁻³ to 1×10²⁰ cm⁻³. In the first embodiment, the second p-side semiconductor layer 22 can function as, for example, a p-side cladding layer.

Ridge

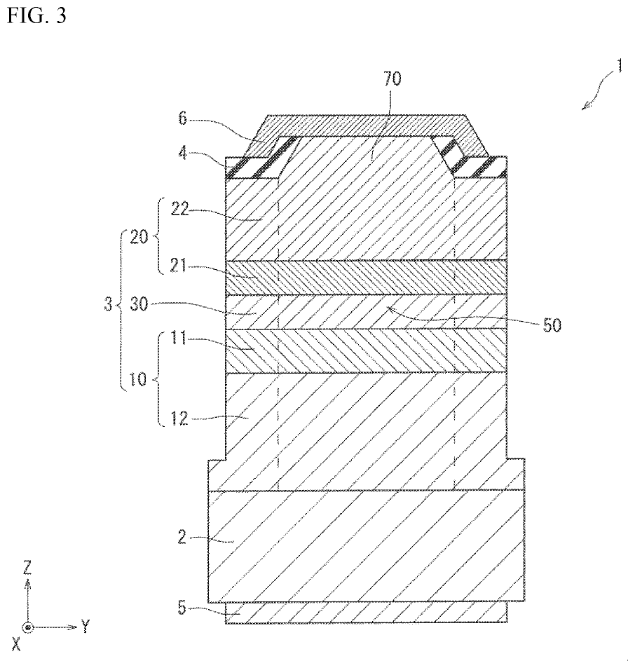

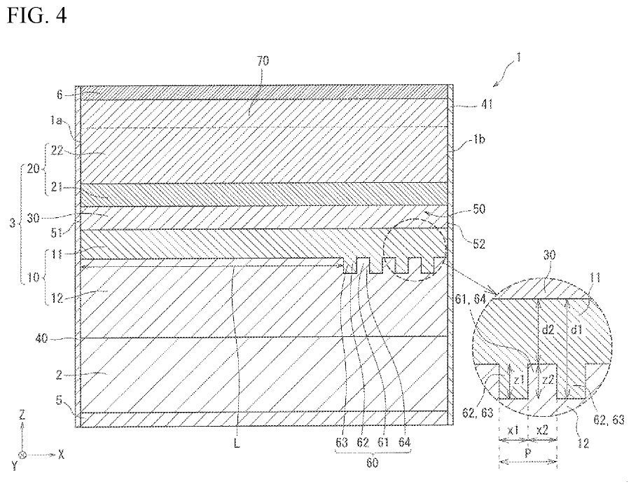

As illustrated in FIGS. 2 to 4, a ridge 70 is provided on an upper surface of the second layer of the semiconductor layer portion 3. FIG. 2 is a cross-sectional view of the narrow portion 53 taken along line II-II in FIG. 1. FIG. 3 is a cross-sectional view of the wide portion 54 taken along line in FIG. 1. FIG. 4 is a cross-sectional view taken along line IV-IV in FIG. 1. The ridge 70 is provided on, for example, a part of the upper surface of the second p-side semiconductor layer 22. As illustrated in FIG. 4, the ridge 70 extends between a first surface 1a and a second surface 1b of the semiconductor laser element 1 in the first direction X. Note that, in FIG. 4, a portion of the second p-side semiconductor layer 22 that corresponds to the ridge 70 is defined by a dotted line to facilitate understanding of the drawing.

The waveguide 50 including the active layer 30 is formed below the ridge 70. The waveguide 50 includes a core and a clad. The core includes the active layer 30 and is a portion through which light emitted from the active layer 30 mainly propagates. The core may include the active layer 30 and at least a part of the semiconductor layer portion 3 located around the active layer 30.

As illustrated in FIGS. 2 and 3, a cross-sectional shape of the ridge 70 in the second direction Y is, for example, a trapezoidal shape having a width in the second direction Y decreasing with increasing distance from the substrate 2. Further, the cross-sectional shape of the ridge 70 in the second direction Y may be a rectangular shape having a width in the second direction Y being constant along the third direction Z. A shape of the ridge 70 in a top view, in particular, a width in the second direction Y is appropriately determined such that a shape of the waveguide 50 described below is obtained.

Although the ridge waveguide is used in the description of the present embodiment, a gain waveguide may be used.

Waveguide

A detailed shape of the waveguide 50 will be described below with reference to FIGS. 1 to 3. FIG. 1 is a schematic top view of the semiconductor laser element 1, in which the waveguide and the diffraction grating 60 are illustrated with broken lines in a perspective view. The broken lines in FIGS. 2 and 3 indicate an example of a range in which the waveguide 50 is included.

As illustrated in FIG. 1, the waveguide 50 extends in the first direction X. The waveguide 50 includes the first end surface 51 and the second end surface 52 located on the side opposite to the first end surface 51 in the first direction X. The waveguide 50 includes the narrow portion 53 and the wide portion 54 having a wider width than the narrow portion 53.

One end surface 53a of the narrow portion 53 is included in the first end surface 51. In the first embodiment, the one end surface 53a of the narrow portion 53 coincides with the first end surface 51. In the narrow portion 53, light generated in the active layer 30 propagates in a transverse multimode. The number of transverse modes of the semiconductor laser element 1 is determined by a width of the narrow portion 53 and a difference in refractive index between the core and the clad of the waveguide. In other words, in the narrow portion 53, a normalized frequency V satisfies the following Formula 1 such that the waveguide in the transverse multimode is formed.

$$V ≧ \frac{N π}{2} \qquad Formula 1$$

(N is an integer of 1 or more)

In Formula 1, N is a mode order of the transverse mode.

In the semiconductor laser element according to the present embodiment, the normalized frequency V is equal to or higher than π/2 as indicated in Formula 1. The normalized frequency V of the narrow portion 53 is preferably in a range from 9π/2 to 100π/2, and more preferably in a range from 9π/2 to 50π/2. As a result, a desired number of transverse modes can be obtained.

The width of the narrow portion 53 is in a range from 15 μm to 90 μm, for example. As a result, a semiconductor laser element having a desired number of transverse modes can be obtained. Note that the width of the narrow portion 53 is constant. “Constant” means that the width changes in a range from 0% to 10%.

For example, the following advantages can be obtained by forming a waveguide in a transverse multimode in the narrow portion 53. A first advantage is a reduction of sudden death at a light-emitting surface. The reason is that in a near-field pattern of an output beam, local concentration of optical density can be reduced as compared with a case of a transverse single mode. A second advantage is a reduction of fluctuations in output. The reason is that a longitudinal mode exists for each transverse mode, and when the semiconductor laser element as a whole oscillates laser light in a longitudinal multimode, fluctuations in total output are small. In a case of a semiconductor laser adopting a longitudinal single mode, when competition with a mode that is adjacent with a free spectral range occurs, an output may fluctuate due to an oscillating longitudinal mode.

The wide portion 54 is continuously connected to the narrow portion 53. The wide portion 54 is located on the second end surface 52 side of the narrow portion 53. One end surface 54a of the wide portion 54 is included in the second end surface 52. In the first embodiment, the one end surface 54a of the wide portion 54 coincides with the second end surface 52. The wide portion 54 includes the first region 55 having a width increasing along the first direction X from the first end surface 51 toward the second end surface 52. In the present embodiment, the wide portion 54 and the first region 55 have the same range. Therefore, one end surface of the first region 55 coincides with the second end surface 52.

The width of the wide portion 54, i.e., the width of the first region 55 changes (increases) such that the number of modes of the transverse multimode determined by the narrow portion 53 is less likely to increase or decrease with propagation. The width of the first region 55 changes in a range greater than 15 μm and equal to or less than 360 μm, for example. For example, the width of the first region 55 increases at a constant rate along the first direction X from the first end surface 51 toward the second end surface 52. In other words, as indicated by the broken lines in FIG. 1, an outline shape of the first region 55 may be a straight line in the top view. Further, the outline shape of the first region 55 may be a curved line in the top view as long as the number of transverse modes is less likely to increase or decrease.

For example, for a change (degree of increase) of the width of the first region 55, a width y2 of an end portion of the first region 55 on the second end surface 52 side is in a range from twice to four times a width y1 of an end portion of the first region 55 on the first end surface 51 side. As a result, heat generated by application of a current is less likely to be biased to the second end surface 52 side, and thermal damage to the semiconductor laser element 1 can be reduced.

As described above, the ridge 70 has a shape overlapping the waveguide 50 in the top view. The ridge 70 in the first embodiment is formed in such a shape that the waveguide 50 having the above-described shape is obtained.

Diffraction Grating

As illustrated in FIG. 1, the diffraction grating 60 is provided on the wide portion 54 in the top view. In the semiconductor laser element according to the first embodiment, the diffraction grating is provided only on the wide portion 54. A wavelength can be selected in a region having a small difference in effective refractive index between transverse modes, i.e., in a region having a small variation in effective refractive index between transverse modes. Therefore, a transverse multimode semiconductor laser element having a small variation in oscillation wavelengths can be obtained. This point will be described by using a result of a simulation.

First, a condition of the simulation will be described. In the simulation, for simplicity, assuming the case of a symmetric three-layer planar waveguide, an eigenvalue equation is solved. The condition of the simulation is set as follows: a refractive index n_{core} of a core=2.5035 and a refractive index n_{clad} of a clad=2.4974. Although effective numbers of parameters are set up to five digits, this is for enhancing the accuracy of the simulation, and the same accuracy is not required in actual manufacture.

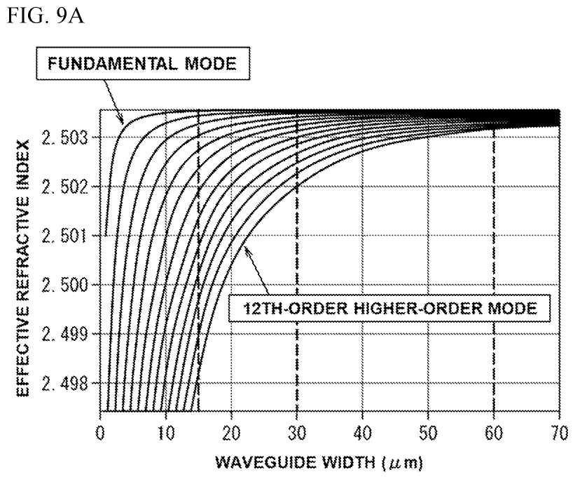

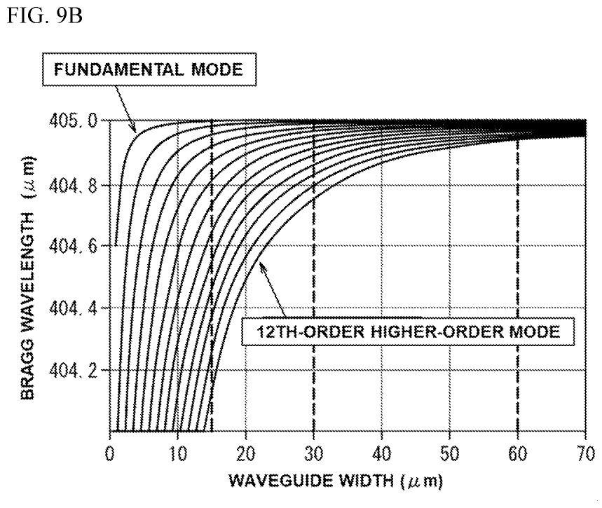

FIG. 9A shows a relationship between a waveguide width and an effective refractive index for each transverse mode. FIG. 9A shows only a transverse mode in which oscillation can be performed when a waveguide width is 15 μm. In other words, FIG. 9A shows a transverse mode in which oscillation can be performed when a waveguide width of the narrow portion 53 is 15 μm with regard to the semiconductor laser element of the present embodiment. In this simulation, a fundamental mode (0-order mode) to 12th-order higher-order mode are plotted. In FIG. 9A, an effective refractive index of the fundamental mode is represented by the leftmost solid line, and an effective refractive index of the 12th-order higher-order mode is represented by the rightmost solid line. Note that the effective refractive index is a value obtained by using a normalized frequency and a normalized propagation constant obtained by solving an eigenvalue equation for each waveguide width.

Next, a Bragg wavelength when the diffraction grating 60 is provided in the waveguide was simulated based on the result in FIG. 9A. FIG. 9B shows a relationship between a waveguide width and a Bragg wavelength at a position where the diffraction grating 60 is provided. In FIG. 9B, a Bragg wavelength of the fundamental mode is represented by the leftmost solid line, and a Bragg wavelength of the 12th-order higher-order mode is represented by the rightmost solid line. The Bragg wavelength is obtained from the equation of Bragg wavelength (λ_{B})=effective refractive index (n_{eff})×pitch (or period, P) of diffraction grating×2. However, a period of the diffraction grating 60 is set to 80.886 nm. This is a value obtained on the assumption that the fundamental mode converges to 405 nm when a waveguide width is sufficiently wide.

Results of simulations at positions where the waveguide width is 15 μm, 30 μm, and 60 μm are compared. In FIGS. 9A and 9B, these positions are indicated by broken lines for ease of reference. First, when attention is paid to the effective refractive index at the positions indicated by the broken lines in FIG. 9A, it is found that a difference in effective refractive index between transverse modes decreases as the waveguide width increases. The reason is that, although the amount of leakage into the clad differs for each transverse mode, the amount of leakage into the clad decreases as the waveguide width increases. Next, when attention is paid to the Bragg wavelength at the positions indicated by the broken lines in FIG. 9B as in FIG. 9A, it is found that a difference in Bragg wavelength between transverse modes decreases as the waveguide width increases. The reason is that a difference in effective refractive index, i.e., a variation in effective refractive index decreases as the waveguide width increases. For example, at the positions where the waveguide width is 15 μm, 30 μm, and 60 μm, a difference in Bragg wavelength between the fundamental mode and the 12th-order higher-order mode, i.e., a difference between the longest wavelength and the shortest wavelength among the Bragg wavelengths is 0.874 nm, 0.235 nm, and 0.063 nm, respectively.

In this simulation, as described above, the waveguide width of the narrow portion 53 is assumed to be 15 μm. Therefore, it can be said that the result obtained when the waveguide width is 15 μm in FIGS. 9A and 9B represents a state in which the waveguide width is not widened. It can be said that the results obtained when the waveguide width is greater than 15 μm, for example, when the waveguide width is 30 μm and 60 μm represent a state in which the waveguide width is widened, that is, a state of the wide portion 54. Therefore, from the results of the simulation, in the semiconductor laser element according to the first embodiment, by providing the diffraction grating 60 on the wide portion 54 having a wider waveguide width than the narrow portion 53, wavelengths can be selected in a region having a smaller variation in the effective refractive index than that of the narrow portion 53, and the transverse multimode semiconductor laser element 1 having a small variation in the Bragg wavelength, i.e., the oscillation wavelengths can be obtained.

For example, in the wide portion 54, the diffraction grating 60 is provided in a portion in which an oscillation wavelength for each transverse mode falls within a range of a wavelength width from 0.01 nm to 0.5 nm, preferably from 0.01 nm to 0.3 nm, and more preferably from 0.01 nm to 0.1 nm.

The diffraction grating 60 is, for example, provided between two adjacent semiconductor layers having different refractive indexes. The diffraction grating 60 includes, for example, one or more first protruding portions provided on a surface of one of the semiconductor layers and one or more second protruding portions provided on a surface of the other semiconductor layer. For example, a plurality of the first protruding portions and a plurality of the second protruding portions are provided. The first protruding portions and the second protruding portions are disposed at intervals in a light propagation direction. For example, the first protruding portions and the second protruding portions are alternately disposed.

For example, as illustrated in FIG. 4, the diffraction grating 60 according to the present embodiment is provided between the first n-side semiconductor layer 11 and the second n-side semiconductor layer 12. The diffraction grating 60 includes one or more second protruding portions 62 provided on the surface of the first n-side semiconductor layer 11 and one or more first protruding portions 61 provided on the surface of the second n-side semiconductor layer 12. The second protruding portion 62 is provided on the surface of the first n-side semiconductor layer 11 on the second n-side semiconductor layer 12 side. In other words, the second protruding portion 62 is provided on the surface on a lower layer side of the first n-side semiconductor layer 11. The first protruding portion 61 is provided on the surface of the second n-side semiconductor layer 12 on the first n-side semiconductor layer 11 side. In other words, the first protruding portion 61 is provided on the surface on an upper layer side of the second n-side semiconductor layer 12. For example, the first protruding portion 61 and a first recessed portion 63 provided on the surface on the upper layer side of the second n-side semiconductor layer 12 are alternately formed at intervals. Alternatively, a second recessed portion 64 and the second protruding portion 62 may be considered as being alternately formed at intervals on the lower layer portion of the first n-side semiconductor layer 11, and the first protruding portion 61 may be considered as being formed on the upper layer portion of the second n-side semiconductor layer 12.

As illustrated in FIGS. 1 and 4, the first protruding portion 61 and the second protruding portion 62 are periodically disposed in the first direction X. Each of the first protruding portion 61 and the second protruding portion 62 is disposed parallel to the second end surface 52. In other words, as illustrated in FIG. 1, a direction in which each of the first protruding portions 61 extends and a direction in which each of the second protruding portions 62 extends are parallel to the second direction Y.

As illustrated in FIG. 1, the diffraction grating 60 may be provided not only on the waveguide 50 but also across the semiconductor layer portion 3 in the second direction Y in the top view. Specifically, in the semiconductor laser element 1, the diffraction grating 60 may be provided on the first n-side semiconductor layer 11 and the second n-side semiconductor layer 12 located on both sides of the waveguide 50 in the second direction Y. A width y3 of the diffraction grating 60 overlapping the wide portion 54 is in a range from, for example, 0.1 times to 0.9 times the width of the diffraction grating 60 in the second direction Y. A width y4 of a region not overlapping the wide portion 54 is in a range from, for example, 0.1 times to 0.9 times the width of the diffraction grating 60 in the second direction Y. Note that the width y4 is a sum of a width of the semiconductor layer portion 3 located on one side of the waveguide 50 in the second direction Y and a width of the semiconductor layer portion 3 located on the other side of the waveguide 50 in the second direction Y.

The diffraction grating 60 is disposed on a portion of the wide portion 54 that has a width equal to or greater than a predetermined value. The diffraction grating 60 is provided on, for example, a portion of the wide portion 54 that has a waveguide width in a range from twice to four times a waveguide width of the narrow portion 53. In this way, a variation in the oscillation wavelengths between transverse modes can be further reduced. When attention is paid to one of a plurality of transverse modes, a range of the oscillation wavelength selected by the diffraction grating is narrow. For example, it is preferable that one longitudinal mode corresponds to one transverse mode. For example, the diffraction grating 60 is provided on a portion of the wide portion 54 that has a waveguide width in a range from 30 μm to 360 μm, preferably from 30 μm to 100 μm, and more preferably from 30 μm to 60 μm. In this case, the waveguide width of the wide portion 54 is sufficiently wider than the waveguide width of the narrow portion 53, and a variation in the oscillation wavelengths between transverse modes can be reduced.

In general, a transverse single mode distributed feedback (DFB) laser element provided with a uniform diffraction grating over the entire length of a waveguide can oscillate laser light at the center of a reflection band of the diffraction grating, i.e., at the Bragg wavelength by including a λ/4 phase shift region. As illustrated in FIG. 4, in the semiconductor laser element 1 according to the first embodiment, since the diffraction grating 60 and the first end surface 51 on which a reflection coating 40 is formed are separated from each other by a distance L, it can be assumed that an effect similar to a λ/4 phase shift is obtained. In this way, the oscillation wavelengths can be easily controlled, and a variation in the oscillation wavelengths of the laser light of the semiconductor laser element 1 can be reduced.

Therefore, in the semiconductor laser element 1 according to the first embodiment, the first end surface 51 and the diffraction grating 60 are separated from each other by the distance L that satisfies the following formula 2, for example. In other words, the diffraction grating 60 is provided on the second end surface 52 side from a position separated from the first end surface 51 by the distance L.

L=(m+1/4)×λ₀/n_{eff} Formula 2

In Formula 2, n_{eff} is an effective refractive index of each transverse mode, m (m≥0) is an integer determined for each effective refractive index, and λ₀ is an oscillation wavelength in vacuum of each transverse mode. In Formula 2, a phase difference generated in the first term including m is an integral multiple of the wavelength, and can thus be ignored. Therefore, a net phase difference generated in Formula 2 is 1/4×λ₀/n_{eff}, which has an effect similar to that of a simple λ/4 phase shift. In the present embodiment, m may be a value of, for example, about several thousand. However, in a case in which the length L cannot be accurately measured, Formula 2 can be considered as being satisfied when an integer is included in a range of m estimated in consideration of a measurement error.

Note that the distance L may include, as an allowable error, a deviation of about a width x1 of the first protruding portion 61 of the diffraction grating 60 in the first direction X (or a width x2 of the second protruding portion 62 in the first direction X). The width x1 of the first protruding portion 61 (or the width x2 of the second protruding portion 62) depends on, for example, a height z1 of the first protruding portion 61 in the third direction Z (or a height z2 of the second protruding portion 62 in the third direction Z), a distance d1 from the first protruding portion 61 to the active layer 30 in the third direction Z (or a distance d2 from the second protruding portion 62 to the active layer 30 in the third direction Z), and the like.

A shape of the first protruding portion 61, the second protruding portion 62, and the first recessed portion 63 (or the second recessed portion 64) is not particularly limited. For example, a cross section orthogonal to the second direction Y may have a sawtooth shape, a sine wave shape, a rectangular shape, a trapezoidal shape, an inverted trapezoidal shape, or the like, and preferably has a rectangular shape, a trapezoidal shape, an inverted trapezoidal shape, or the like.

A pitch P of the diffraction grating 60 is, for example, in a range from 20 nm to 500 nm, preferably from 30 nm to 250 nm, and more preferably from 40 nm to 140 nm. Note that, in the first direction X, the width x1 of the first protruding portion 61 and the width x2 of the second protruding portion 62 are preferably the same, but may be different.

In the third direction Z, each of the height z1 of the first protruding portion 61 and the height z2 of the second protruding portion 62 is, for example, in a range from 50 nm to 300 nm, and preferably from 50 nm to 150 nm. Note that the height z1 of the first protruding portion 61 and the height z2 of the second protruding portion 62 may be the same or different, and more preferably the same.

With such size and depth, a desired coupling coefficient is obtained and wavelength selectivity for each transverse mode is improved.

Semiconductor Laser Element

The semiconductor laser element 1 according to the first embodiment having the configuration described above functions as a DFB laser element.

As illustrated in FIG. 1, the semiconductor laser element 1 includes the first surface 1a and the second surface 1b on a side opposite to the first surface 1a in the first direction X. The first surface 1a and the second surface 1b extend on a plane extending in the second direction Y and the third direction Z. The reflection coating (HR coating) 40 is formed on the first surface 1a. An anti-reflection coating (AR coating) 41 is formed on the second surface 1b. The semiconductor laser element 1 includes the diffraction grating 60 on the wide portion 54 of the waveguide 50, and an optical resonator in which the first direction X is a resonance direction (light waveguide direction) is formed in the semiconductor laser element 1. The second surface 1b is a light-emitting surface mainly having a function of emitting light to the outside of the semiconductor laser element 1.

Electrode

As illustrated in FIGS. 2, 3, and 4, the semiconductor laser element 1 includes a first electrode 5 and a second electrode 6.

The first electrode 5 is a negative electrode. The first electrode 5 is provided so as to be electrically connected to the second n-side semiconductor layer 12 while ensuring ohmic contact therewith. For example, the first electrode 5 is provided in contact with the second n-side semiconductor layer 12. Further, the first electrode 5 may be disposed on a lower surface of the substrate 2 when, for example, the substrate 2 has conductivity and can ensure ohmic contact properties. The first electrode 5 has, for example, a multilayer structure of a metal layer. Examples of a material of the first electrode 5 include a single-layer film or a multilayer film of a metal such as Ni, Rh, Cr, Au, W, Pt, Ti, and Al, an alloy thereof, a conductive oxide containing at least a metal selected from Zn, In, and Sn, or the like. Examples of the conductive oxide include indium tin oxide (ITO), indium zinc oxide (IZO), gallium-doped zinc oxide (GZO), and the like. The first electrode 5 has, for example, a multilayer structure of Ti and Au.

The second electrode 6 is a positive electrode. The second electrode 6 is provided in contact with an upper surface of the ridge 70. The second electrode 6 has, for example, a multilayer structure of a metal layer. A material of the second electrode 6 can be selected from the same materials as those of the first electrode 5. The second electrode 6 has, for example, a multilayer structure of Ni and Au.

The second electrode 6 may be provided in a range wider than the upper surface of the ridge However, in this case, as illustrated in FIGS. 2 and 3, an insulating member 4 is provided between the second electrode 6 and a portion of the upper surface of the second layer 20 except the upper surface of the ridge 70.

In the semiconductor laser element 1 formed in the manner described above, an output of 90% or more of a total output of light emitted from the second end surface 52 is included in a range of a wavelength width from 0.01 nm to 0.5 nm, for example. In other words, a plurality of oscillation wavelengths of the light fall within a range from 0.01 nm to 0.5 nm, for example. This means that a variation in the oscillation wavelengths of the laser light between transverse modes, whose wavelengths are selected by the diffraction grating 60, are small. This can be seen by analyzing the power of the output light and its wavelength dispersion.

In the semiconductor laser element 1 formed in the manner described above, a M² factor of the light emitted from the second end surface 52 is, for example, in a range from 5 to 50. As a result, a desired number of transverse modes can be obtained. For example, 10 or more and 100 or less transverse modes or preferably 10 or more and 50 or less transverse modes can be obtained.

The M² factor is acquired by comparing an actual beam shape with an ideal shape of a Gaussian beam. The M² factor is defined by the following Formula 3 using a beam waist ω₀ of the semiconductor laser element 1, a divergence angle θ of the semiconductor laser element 1, and an oscillation wavelength λ of the semiconductor laser element 1.

$${M}^{2} = \frac{π {ω}_{0} θ}{λ} \qquad Formula 3$$

In the semiconductor laser element 1 formed in the manner described above, the waveguide 50 includes the wide portion 54 having a wider width than the narrow portion 53, and the diffraction grating 60 is provided on the wide portion 54. In this way, a wavelength of light in the transverse multimode propagating through the narrow portion 53 is selected by the diffraction grating 60 in the wide portion 54 having a variation in the effective refractive index of each transverse mode smaller than that of the narrow portion 53. Therefore, an oscillation wavelength of each transverse mode can fall within a predetermined range of a wavelength width, and a variation in the oscillation wavelengths between transverse modes can be reduced in the semiconductor laser element 1.

As described above, in the first embodiment, the first n-side semiconductor layer 11 is described as the n-side light guide layer and the second n-side semiconductor layer 12 is described as the n-side cladding layer, but the present disclosure is not limited thereto. For example, another semiconductor layer may be provided, as an n-side cladding layer, between the second n-side semiconductor layer 12 and the substrate 2. In that case, both of the first n-side semiconductor layer 11 and the second n-side semiconductor layer 12 may be n-side light guide layers. Further, a semiconductor layer may be provided, as an n-side light guide layer, between the active layer 30 and the first n-side semiconductor layer 11. In that case, both of the first n-side semiconductor layer 11 and the second n-side semiconductor layer 12 may be n-side cladding layers. Alternatively, the first n-side semiconductor layer 11 may be an n-side light guide layer and the second n-side semiconductor layer 12 may be an n-side cladding layer. Therefore, the diffraction grating 60 may be provided in any position between an n-side light guide layer and an n-side light guide layer, between an n-side light guide layer and an n-side cladding layer, or between an n-side cladding layer and an n-side cladding layer.

The diffraction grating 60 may be provided on the p-side semiconductor layer side. For example, another semiconductor layer may be provided between the active layer 30 and the first p-side semiconductor layer 21 and/or between the second p-side semiconductor layer 22 and the second electrode 6. Therefore, the diffraction grating 60 may be provided in any position between a p-side light guide layer and a p-side light guide layer, between a p-side light guide layer and a p-side cladding layer, or between a p-side cladding layer and a p-side cladding layer.

2. Manufacturing Method

A method for manufacturing the semiconductor laser element 1 according to the present embodiment includes steps of: (i) preparing a substrate; (ii) forming a semiconductor layer portion and a diffraction grating; (iii) forming a ridge; and (iv) forming electrodes. Each semiconductor layer of the semiconductor layer portion can be formed by any method known in the field, such as a metal organic chemical vapor deposition (MOCVD) method, a halide vapor phase epitaxy (HVPE) method, a molecular beam epitaxy (MBE) method, or a sputtering method.

(i) Step of Preparing Substrate

First, the substrate 2 made of, for example, GaN is prepared.

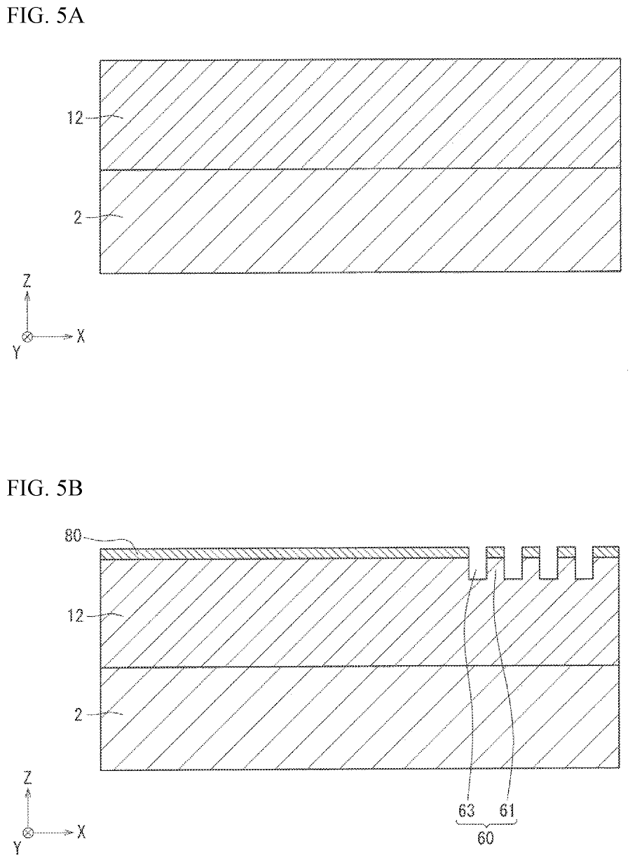

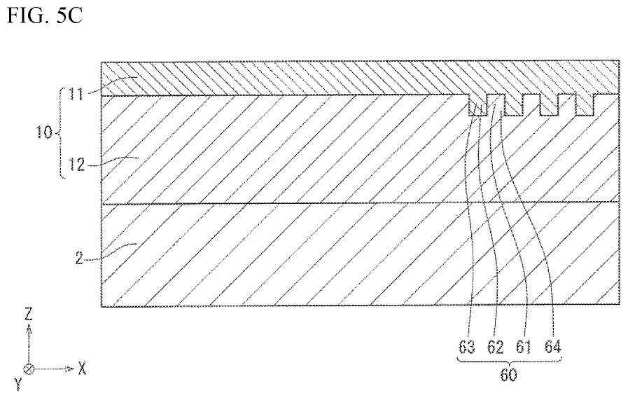

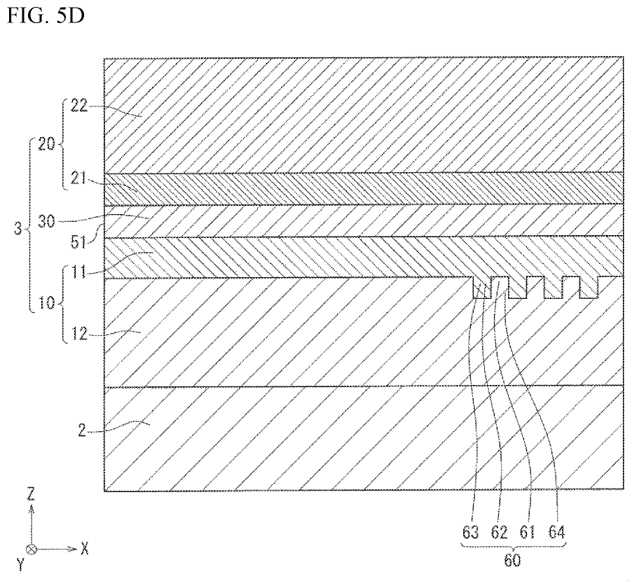

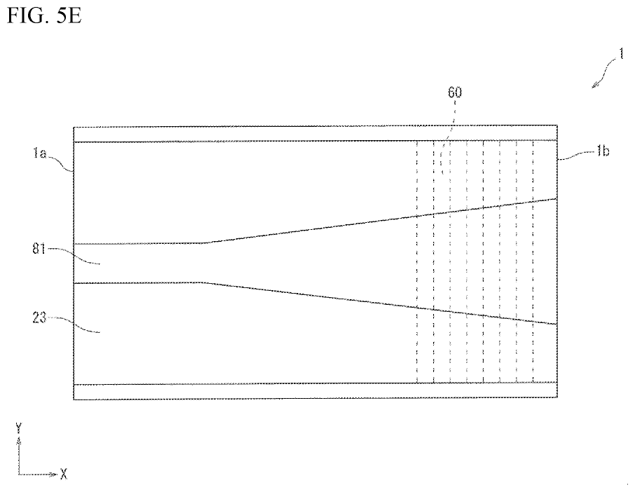

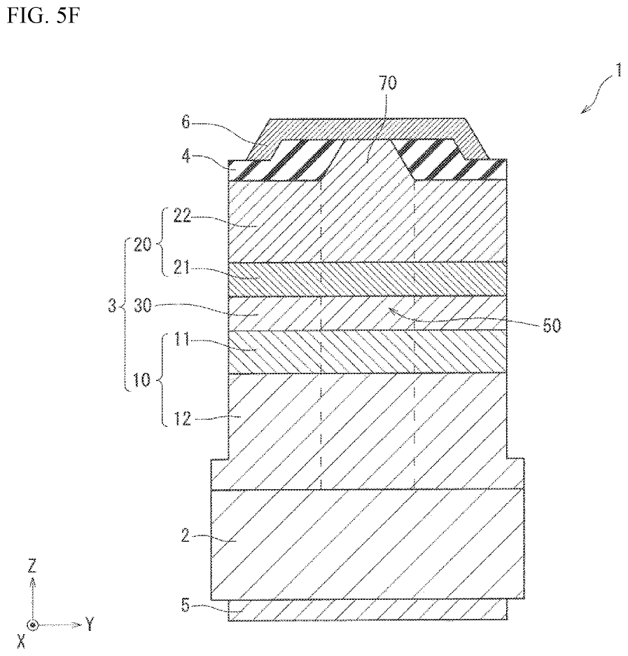

(ii) Step of Forming Semiconductor Layer Portion and Diffraction Grating Subsequently, as illustrated in FIG. 5A, the second n-side semiconductor layer 12 is formed on the substrate 2. The second n-side semiconductor layer 12 may be formed after a foundation layer is provided on the substrate 2.

As a method for forming the diffraction grating 60, first, the second n-side semiconductor layer 12 is formed, and then a mask pattern 80 is formed as illustrated in FIG. 5B. A method for forming the mask pattern 80 includes, for example, a photolithography step, an etching step, and the like using a method known in the field, such as a double resist method, a contact mask exposure method, an electron beam lithography method, and a phase shift method. Subsequently, etching is performed using the mask pattern 80 as a mask to form the first recessed portion 63 and the first protruding portion 61. Subsequently, as illustrated in FIG. 5C, the mask pattern 80 is removed, and the first recessed portion 63 of the second n-side semiconductor layer 12 can be formed by being filled with the second protruding portion 62 of the first n-side semiconductor layer 11.

The mask pattern 80 at this time can be formed using any of various resists, an oxide or a nitride such as Al₂O₃, ZrO₂, SiO₂, TiO₂, Ta₂O₅, AlN, or SiN, or a single-layer film or a multilayer film of a metal such as nickel or chromium. A film thickness thereof is preferably in a range from 10 nm to 500 nm, for example. In this way, it is possible to form the first protruding portion 61 and the second protruding portion 62 at desired heights.

In particular, when patterning is performed using a member having a low refractive index, such as SiO₂, TiO₂, ZrO₂, Al₂O₃, SiN, or AlN, as the mask pattern 80, the first n-side semiconductor layer 11 may be grown without removing the mask pattern 80. In this way, a member having a lower refractive index than the nitride semiconductor is disposed on an upper surface of the first protruding portion 61, and the effect of the diffraction grating 60 can be further improved by the member having a low refractive index.

When the semiconductor layer is etched using the mask pattern 80 to form the first protruding portion 61 and the first recessed portion 63, the etching is performed by, for example, dry etching. For example, when dry etching is used, etching is preferably performed at a pressure (a constant pressure or an appropriately changed pressure) within a range from 0.05 Pa to 10 Pa. In this way, etching to a desired depth can be efficiently performed.

After the first n-side semiconductor layer 11 is formed, the active layer 30 and the second layer 20 are formed in this order on the first n-side semiconductor layer 11 as illustrated in FIG. 5D to prepare the semiconductor layer portion 3. In the second layer 20, the first p-side semiconductor layer 21 and the second p-side semiconductor layer 22 may be formed in this order from the substrate 2 side.

When the active layer 30 has a multiple quantum well structure, a desired number of barrier layers and well layers are alternately formed sequentially from the substrate 2 side to form the active layer 30. Note that, in this case, the step of forming the active layer 30 is completed by the step of forming the barrier layer.

(iii) Step of Forming Ridge

As illustrated in FIG. 5E, after the semiconductor layer portion 3 is formed, the ridge 70 is formed on a surface of the semiconductor layer portion 3. The ridge 70 is provided such that a narrow portion and a wide portion having a wider waveguide width than the narrow portion are formed.

For example, a protective film made of a Si oxide (mainly SiO₂) is formed on substantially the entire surface of the second p-side semiconductor layer 22 (p-side cladding layer) with a CVD device, a mask having a predetermined shape is then formed on the protective film, and a protective film 81 having a striped shape and a tapered shape is formed by photolithography using a reactive ion etching (RIE) apparatus or the like. In the protective film 81, a width of the tapered portion is wider than a width of the striped portion. The ridge 70 can be formed by, for example, etching the second p-side semiconductor layer 22 by using the protective film 81 as a mask. The ridge 70 is usually formed by etching from the second p-side semiconductor layer 22, and is preferably formed closer to the second layer 20 than to the active layer 30. For example, the ridge 70 may be formed by etching to the middle of the second p-side semiconductor layer 22, or may be formed by etching from the second p-side semiconductor layer 22 to the middle of the first p-side semiconductor layer 21.

(iv) Step of Forming Electrodes

As illustrated in FIG. 5F, the second electrode 6 is formed on the upper surface of the ridge and the first electrode 5 is formed on the lower surface of the substrate 2. The second electrode 6 is formed in contact with the upper surface of the ridge 70 so as to cover the upper surface of the ridge 70. In order to prevent the second electrode 6 from being formed in contact with a portion other than the upper surface of the ridge 70, the upper surface of the ridge 70 of the upper surface of the semiconductor layer portion 3 is covered with a mask, and the insulating member 4 is disposed on the upper surface of the semiconductor layer portion 3. The insulating member 4 is disposed by sputtering or the like, for example. Subsequently, the mask and the insulating member 4 disposed on the mask are removed by etching, for example. The second electrode 6 is formed on the exposed upper surface of the ridge 70 by, for example, sputtering.

The first electrode 5 is disposed so as to be electrically connected to the second p-side semiconductor layer 22. When the substrate 2 has conductivity, the first electrode 5 can be formed on the lower surface of the substrate 2. The first electrode 5 is formed by sputtering, for example.

The first electrode 5 and the second electrode 6 may be formed by appropriately using a known method other than sputtering. The first electrode 5 and the second electrode 6 may be formed by, for example, a lift-off process or an etching process using a resist.

Note that a light-transmitting electrode may be formed between the first electrode 5 and the substrate 2. The first electrode 5 may be formed directly on the first n-side semiconductor layer 11 or the second n-side semiconductor layer 12.

After the step of forming the electrodes, a reflection coating may be formed on the first surface 1a and an anti-reflection coating may be formed on the second surface 1b. The reflection coating and the anti-reflection coating can be formed by vapor deposition, sputtering, or the like. The reflection coating and the anti-reflection coating may be formed at any timing as long as they are formed in the step of forming the semiconductor layer portion and the diffraction grating.

### 3. Second Embodiment

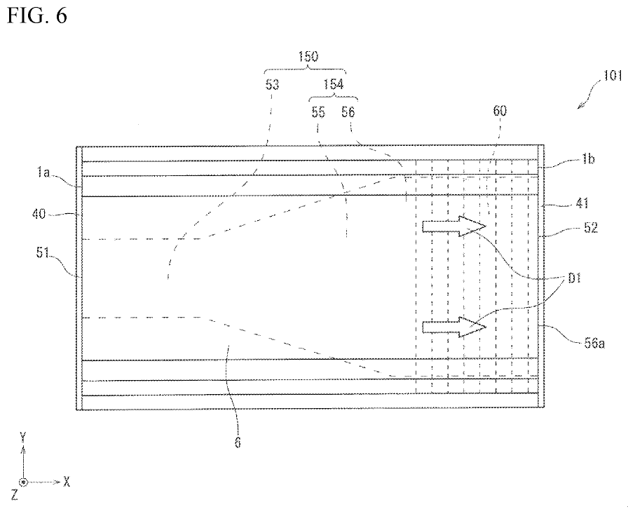

As illustrated in FIG. 6, a semiconductor laser element 101 according to the second embodiment is different from the semiconductor laser element 1 according to the first embodiment in that a wide portion includes a second region 56 having a constant width. Here, “constant” includes, for example, a case in which the width changes in a range from 0% to 10%.

The second region 56 is continuously connected to a first region 55. The second region 56 is located between the first region 55 and a second end surface 52. One end surface 56a of the second region 56 is included in, for example, the second end surface 52. A diffraction grating is provided in, for example, the second region 56. The diffraction grating 60 may be provided across the first region 55 and the second region 56.

By providing the diffraction grating 60 in the second region 56 in this manner, a propagation direction D1 of light in the diffraction grating 60 is orthogonal to the diffraction grating 60. Specifically, the propagation direction D1 of light in the diffraction grating 60 is orthogonal to a direction in which each first protruding portion 61 extends and a direction in which each second protruding portion 62 extends, that is, the second direction Y. Thus, a wave surface of the light propagating through the diffraction grating 60 and the diffraction grating 60 are parallel to each other, and a loss of the propagating light can be reduced. Further, a variation in oscillation wavelengths of the semiconductor laser element 1 can be reduced.

### 4. Third Embodiment

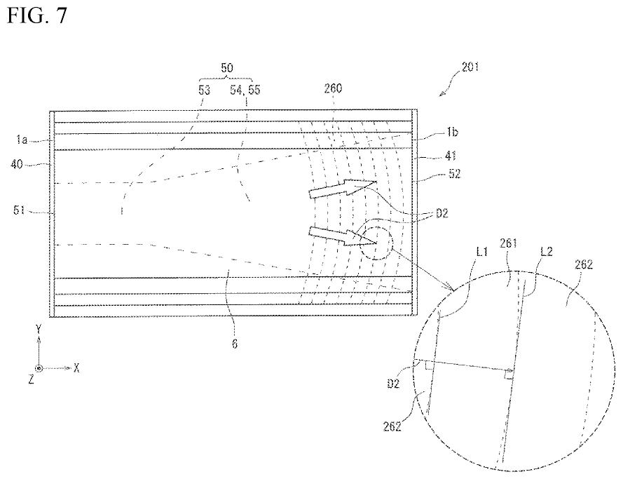

As illustrated in FIG. 7, a semiconductor laser element 201 according to a third embodiment is different from the semiconductor laser element 1 according to the first embodiment in that a diffraction grating 260 is disposed so as to be curved in a shape protruding from a first end surface 51 toward a second end surface 52 in the top view.

First protruding portions 261 and second protruding portions 262 are each disposed so as to be curved in a shape protruding from the first end surface 51 toward the second end surface 52 in the top view. A tangent line L1 of an inner periphery of each of the first protruding portions 261 and a tangent line L2 of an inner periphery of each of the second protruding portions 262 are parallel to a wave surface of propagating light, for example.

Since the diffraction grating 260 is disposed so as to be curved in a shape protruding from the first end surface 51 toward the second end surface 52 in this manner, a propagation direction D2 of light in the diffraction grating 260 can be orthogonal to the diffraction grating 260. In this way, a wave surface of the light propagating through the diffraction grating 260 and the diffraction grating 260 are parallel to each other, and a loss of the propagating light can be reduced. Further, a variation in oscillation wavelengths of the semiconductor laser element 1 can be reduced.

Note that the diffraction grating 260 curved in the manner described above is also applicable to the case in which the diffraction grating is provided in the first region 55 in the semiconductor laser element 101 according to the second embodiment.

### 5. Fourth Embodiment

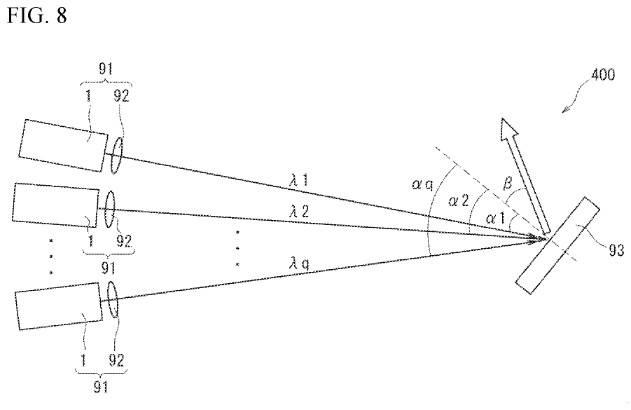

As illustrated in FIG. 8, a fourth embodiment relates to a light source device 400 including any of the semiconductor laser elements 1, 101, and 201 according to the first to third embodiments described above. The light source device 400 can be used for wavelength beam combining (WBC). Thus, an output of the light source device can be improved.

The light source device 400 includes a plurality of light source units 91 and a second diffraction grating 93 configured to diffract and combine light emitted from the plurality of light source units. Each of the plurality of light source units 91 includes the semiconductor laser element 1 (or 101 or 201) according to any of the first to third embodiments and a collimating lens 92. Oscillation wavelengths λ₁, λ₂, . . . , λ_{q} of the semiconductor laser elements 1 of the light source units 91 are different from each other. q is an integer for distinguishing the plurality of light source units 91. Note that the semiconductor laser element 1 is a longitudinal multimode type semiconductor laser, and the oscillation wavelength λ_{q} output from each of the light source units 91 includes a plurality of oscillation wavelengths. However, the number of longitudinal modes need not be the same at all the oscillation wavelengths λ_{q}. The collimating lens 92 is disposed at a position on which light emitted from the semiconductor laser element 1 (or 101 or 201) is incident. Note that the light source unit 91 does not need to be formed of only a set of one semiconductor laser element 1 (or 101 or 201) and one collimating lens 92, and may include a plurality of sets thereof. In that case, an output of the light source unit 91 for each oscillation wavelength λ_{q} can be increased.

The second diffraction grating 93 combines light emitted from the plurality of light source units 91. The second diffraction grating 93 includes, for example, grooves and protrusions that are periodically arranged. Each of the light source units 91 is disposed such that a relationship between an incident angle α at which the light emitted from the collimating lens 92 is incident on the second diffraction grating 93 and a diffraction angle β of the light diffracted by the second diffraction grating 93 satisfies the following Formula 4.

sinα+sinβ=Glλ Formula 4

In Formula 4, G is the number of grooves (g/mm) of the diffraction grating of the second diffraction grating 93, 1 is the order, and λ is the oscillation wavelength (nm) of the semiconductor laser element 1.

The oscillation wavelength λ_{q} output from each of the light source units 91 includes a plurality of oscillation wavelengths, and the diffraction angle β corresponding to each of the oscillation wavelengths is different. However, in the semiconductor laser element 1 included in the light source unit 91, the first diffraction grating is provided on the wide portion, and a variation in oscillation wavelength is small. For example, an oscillation wavelength for each transverse mode is included in a range of a wavelength width from 0.01 nm to 0.5 nm. Thus, a deviation of the diffraction angle β corresponding to the oscillation wavelength for each transverse mode is small. Therefore, light emitted from the light source units 91 can be multiplexed by the second diffraction grating 93 at substantially the same diffraction angle. As a result, the light emitted from the light source device 400 has a high optical output.

The light emitted from the light source device 400 formed in the manner described above is introduced into, for example, a multimode fiber. A core diameter of the multimode fiber is greater than a width of the second end surface (light-emitting surface) 52 of each semiconductor laser element 1. The core diameter of the multimode fiber is, for example, in a range from 90 μm to 400 μm.

### 6. Modified Example

Although the semiconductor laser elements 1, 101, and 201 according to the first to fourth embodiments are DFB semiconductor laser elements, they may be semiconductor laser elements of a distributed Bragg reflector (DBR) laser. In a case of a DBR-type semiconductor laser element, no electrode is included immediately above or immediately below a position where the first diffraction grating 60 is provided. For example, the narrow portion includes the active layer, and the wide portion does not include the active layer.

### 7. Other Configurations

Further, for example, the present disclosure can have the following configurations.

Supplementary Note 1

A semiconductor laser element comprising:
a substrate; and
a semiconductor layer portion disposed on the substrate and comprising a waveguide that comprises an active layer; wherein:
the waveguide includes a wide portion comprising a first diffraction grating, and a narrow portion through which light generated in the active layer propagates in a transverse multimode, wherein a waveguide width of the narrow portion is narrower than a waveguide width of the wide portion;
the waveguide includes a first end surface including an end surface of the narrow portion, and a second end surface located on a side opposite to the first end surface; and
the wide portion is continuously connected to the narrow portion, and comprises a first region having a waveguide width increasing from a side of the first end surface toward a side of the second end surface.

Supplementary Note 2

The semiconductor laser element according to supplementary note 1, wherein:
the waveguide further comprises a second region;
the second region is continuously connected to the first region;
a waveguide width in the second region is a constant; and
the second region comprises the first diffraction grating.

Supplementary Note 3

The semiconductor laser element according to supplementary note 1 or 2, wherein:
the semiconductor layer portion includes a first semiconductor layer having a first refractive index, and a second semiconductor layer having a second refractive index different from the first refractive index; and
in the first diffraction grating, one or more first protruding portions provided on a surface of the first semiconductor layer and one or more second protruding portions provided on a surface of the second semiconductor layer are periodically disposed in a light propagation direction in the first diffraction grating.

Supplementary Note 4

The semiconductor laser element according to supplementary note 3, wherein:
the first semiconductor layer is disposed between the active layer and the second semiconductor layer.

Supplementary Note 5

The semiconductor laser element according to supplementary note 3 or 4, wherein:
each of the first protruding portions and each of the second protruding portions are disposed parallel to the second end surface.

Supplementary Note 6

The semiconductor laser element according to supplementary note 3 or 4, wherein:
each of the first protruding portions and each of the second protruding portions are disposed such that the first protruding portion and the second protruding portion are curved in a shape protruding from the side of the first end surface toward the side of the second end surface.

Supplementary Note 7

The semiconductor laser element according to supplementary note 6, wherein:
a tangent line of an inner periphery of each of the first protruding portions and a tangent line of an inner periphery of each of the second protruding portions are parallel to a wave surface of propagating light.

Supplementary Note 8

The semiconductor laser element according to any one of supplementary notes 1 to 7, wherein:
90% or more of a total output of light emitted from the second end surface has a wavelength width in a range of 0.01 nm to 0.5 nm.

Supplementary Note 9

The semiconductor laser element according to any one of supplementary notes 1 to 8, wherein:
a waveguide width of a portion provided with the diffraction grating is in a range from twice to four times the waveguide width of the narrow portion.

Supplementary Note 10

The semiconductor laser element according to any one of supplementary notes 1 to 9, wherein:
the waveguide width of the narrow portion is in a range from 15 μm to 90 μm.

Supplementary Note 11

The semiconductor laser element according to any one of supplementary notes 1 to 10, wherein:
a waveguide width of a portion provided with the diffraction grating is in a range from 30 μm to 360 μm.

Supplementary Note 12

The semiconductor laser element according to any one of supplementary notes 1 to 11, wherein:
a distance from the first end surface to the diffraction grating is represented as (m+1/4)×λ₀/n_{eff} using an integer m, an effective refractive index n_{eff} of each transverse mode, and a wavelength λ₀ in vacuum of each transverse mode.

Supplementary Note 13

The semiconductor laser element according to any one of supplementary notes 1 to 12, wherein:
a M² factor of light emitted from the second end surface is in a range from 5 to 50.

Supplementary Note 14

A light source device comprising:
a plurality of light source units, each comprising:
   the semiconductor laser element according to any one of supplementary notes 1 to 13, and
   a collimating lens on which light emitted from the semiconductor laser element is incident; and
   a second diffraction grating configured to diffract and combine light emitted from the plurality of light source units.

The embodiments and the modified example of the present disclosure have been described thus far, but the described embodiments may be changed in details of the configurations, and changes in the combination and order of the elements in the embodiments and the modified example, and the like can be made without departing from the scope and spirit of the present disclosure.

1. A semiconductor laser element comprising:
a substrate; and
a semiconductor layer portion disposed on the substrate and comprising a waveguide that comprises an active layer; wherein:
the waveguide includes a wide portion comprising a first diffraction grating, and a narrow portion through which light generated in the active layer propagates in a transverse multimode, wherein a waveguide width of the narrow portion is narrower than a waveguide width of the wide portion;
the waveguide includes a first end surface including an end surface of the narrow portion, and a second end surface located on a side opposite to the first end surface; and
the wide portion is continuously connected to the narrow portion, and comprises a first region having a waveguide width increasing from a side of the first end surface toward a side of the second end surface.

2. The semiconductor laser element according to claim 1, wherein:
the waveguide further comprises a second region;
the second region is continuously connected to the first region;
a waveguide width in the second region is a constant; and
the second region comprises the first diffraction grating.

3. The semiconductor laser element according to claim 1, wherein:
the semiconductor layer portion includes a first semiconductor layer having a first refractive index, and a second semiconductor layer having a second refractive index different from the first refractive index; and
in the first diffraction grating, one or more first protruding portions provided on a surface of the first semiconductor layer and one or more second protruding portions provided on a surface of the second semiconductor layer are periodically disposed in a light propagation direction in the first diffraction grating.

4. The semiconductor laser element according to claim 3, wherein:
the first semiconductor layer is disposed between the active layer and the second semiconductor layer.

5. The semiconductor laser element according to claim 3, wherein:
each of the first protruding portions and each of the second protruding portions are disposed parallel to the second end surface.

6. The semiconductor laser element according to claim 3, wherein:
each of the first protruding portions and each of the second protruding portions are disposed such that the first protruding portion and the second protruding portion are curved in a shape protruding from the side of the first end surface toward the side of the second end surface.

7. The semiconductor laser element according to claim 6, wherein:
a tangent line of an inner periphery of each of the first protruding portions and a tangent line of an inner periphery of each of the second protruding portions are parallel to a wave surface of propagating light.

8. The semiconductor laser element according to claim 1, wherein:
90% or more of a total output of light emitted from the second end surface has a wavelength width in a range of 0.01 nm to 0.5 nm.

9. The semiconductor laser element according to claim 1, wherein:
a waveguide width of a portion provided with the first diffraction grating is in a range from twice to four times the waveguide width of the narrow portion.

10. The semiconductor laser element according to claim 5, wherein:
a waveguide width of a portion provided with the first diffraction grating is in a range from twice to four times the waveguide width of the narrow portion.

11. The semiconductor laser element according to claim 1, wherein:
the waveguide width of the narrow portion is in a range from 15 μm to 90 μm.

12. The semiconductor laser element according to claim 5, wherein:
the waveguide width of the narrow portion is in a range from 15 μm to 90 μm.

13. The semiconductor laser element according to claim 1, wherein:
a waveguide width of a portion provided with the first diffraction grating is in a range from 30 μm to 360 μm.

14. The semiconductor laser element according to claim 5, wherein:
a waveguide width of a portion provided with the first diffraction grating is in a range from 30 μm to 360 μm.

15. The semiconductor laser element according to claim 1, wherein:
a distance from the first end surface to the first diffraction grating is represented as (m+1/4)×λ₀/n_{eff} using an integer m, an effective refractive index n_{eff} of each transverse mode, and a wavelength λ₀ in vacuum of each transverse mode.

16. The semiconductor laser element according to claim 1, wherein:
a M² factor of light emitted from the second end surface is in a range from 5 to 50.

17. A light source device comprising:
a plurality of light source units, each comprising:
the semiconductor laser element according to claim 1, and
a collimating lens on which light emitted from the semiconductor laser element is incident; and
a second diffraction grating configured to diffract and combine light emitted from the plurality of light source units.
